(19) United States
(12) Patent Application Publication
(10) Pub. No.: US 2016/0277037 A1
(43) Pub. Date: Sep. 22, 2016

(54) COMMUNICATION APPARATUS, COMMUNICATION SYSTEM, AND COMMUNICATION METHOD

(71) Applicant: KABUSHIKI KAISHA TOSHIBA, Tokyo (JP)

(72) Inventor: Hirotsugu KAJIHARA, Yokohama Kanagawa (JP)

(73) Assignee: KABUSHIKI KAISHA TOSHIBA, Tokyo (JP)

(21) Appl. No.: 14/848,287

(22) Filed: Sep. 8, 2015

(30) Foreign Application Priority Data
Mar. 16, 2015 (JP) 2015-052514

(51) Int. Cl. H03M 13/27; H04L 1/00

(52) U.S. Cl. CPC H03M 13/2792; H04L 1/0041; H04L 1/0045

(57) ABSTRACT

A communication apparatus includes a deinterleaver and an error corrector. The deinterleaver sets, as an input, a third error-correction-code sequence obtained by rearranging bit positions of a second error-correction-code sequence in which two or more terminated first error-correction-code sequences are repeated from the terminated first error-correction-code sequences in accordance with a first rule. The deinterleaver rearranges bit positions of the third error-correction-code sequence in accordance with a second rule that is different from the first rule to configure a fourth error-correction-code sequence including one or more of the terminated first error-correction-code sequences. The error corrector performs error correction based on the fourth error-correction-code sequence. The second rule used by the deinterleaver is to extract bits capable of configuring the fourth error-correction-code sequence in order from a head of the third error-correction-code sequence.

### CROSS REFERENCE TO RELATED APPLICATIONS

This application is based upon and claims the benefit of priority from the prior Japanese Patent Application No. 2015-52514, filed on Mar. 16, 2015, the entire contents of which are incorporated herein by reference.

### FIELD

Embodiments relate to a communication apparatus, a communication system, and a communication method.

### BACKGROUND

A physical-layer frame format of IEEE 802.11ac includes a Data field storing therein a MAC-layer frame format as a field subsequent to a VHT-SIG-B (Very High Throughput-SIGNAL-B). As a coding (modulation) method of the Data field, either binary convolutional coding (hereinafter, also “BCC coding”) or low-density parity-check coding (hereinafter, also “LDPC coding”) can be selected. The parameter required for encoding the Data field is specified by an MCS index (Modulation and Coding Method). In the following descriptions, the parameter for applying LDPC coding is defined as “LDPC coding parameter”.

A communication apparatus having received a Multi User Format (hereinafter, “MU format”) with LDPC encoding in IEEE 802.11ac needs to demodulate a VHT-SIG-B field so as to obtain an MCS index, thereby obtaining an LDPC coding parameter calculated from the MCS index. Otherwise, the LDPC coding parameter is unknown, and thus the data of the Data field cannot be demodulated.

Therefore, in conventional communication apparatuses, because demodulation of data of a VHT-SIG-B takes time, there has been a problem that demodulation processing of a Data field is delayed.

### BRIEF DESCRIPTION OF THE DRAWINGS

FIG. 1 is a block diagram of a communication system 1 according to an embodiment;

FIG. 2 shows a frame format of IEEE 802.11ac;

FIG. 3 shows an operation example of the communication system 1 in FIG. 1;

FIG. 4 is a timing chart showing an operation example of the communication system 1 in FIG. 1; and

FIG. 5 is a timing chart showing an operation example of a communication system according to a comparative example.

### DETAILED DESCRIPTION

A communication apparatus according to an embodiment includes a deinterleaver and an error corrector. The deinterleaver sets, as an input, a third error-correction-code sequence obtained by rearranging bit positions of a second error-correction-code sequence in which two or more terminated first error-correction-code sequences are repeated from the terminated first error-correction-code sequences in accordance with a first rule. The deinterleaver rearranges bit positions of an input third error-correction-code sequence in accordance with a second rule that is different from the first rule to configure a fourth error-correction-code sequence including one or more of the terminated first error-correction-code sequences. The error corrector performs error correction based on the fourth error-correction-code sequence. The second rule used by the deinterleaver is to extract bits capable of configuring the fourth error-correction-code sequence in order from a head of the third error-correction-code sequence.

Embodiments will now be explained with reference to the accompanying drawings. The present invention is not limited to the embodiments.

A physical-layer frame format of IEEE 802.11ac includes a field referred to as “VHT-SIG-A (Very High Throughput-SIGNAL-A)” and a field referred to as “VHT-SIG-B” described above. In each of the VHT-SIG-A and the VHT-SIG-B, frame configuration information such as a length of a MAC-layer frame format included in the frame and an MCS index for specifying a communication speed or the like described above has been described. To handle BCC coding and burst errors, a process referred to as “interleaving” is performed on data of the VHT-SIG-A and the VHT-SIG-B.

In a physical-layer frame format of IEEE 802.11ac, a Single User Format (hereinafter, “SU format”) and an MU format described above are specified. Between the SU format and the MU format, there is a difference in frame configuration information included in the VHT-SIG-A field and the VHT-SIG-B field. The largest difference between these formats is a position where an MCS index has been described. In the SU format, the MCS index has been described in the VHT-SIG-A. In the MU format, the MCS index has been described in the VHT-SIG-B.

For example, to quickly perform wireless communication using the physical-layer frame format of IEEE 802.11ac described above, a communication system according to the present embodiment is configured as follows.

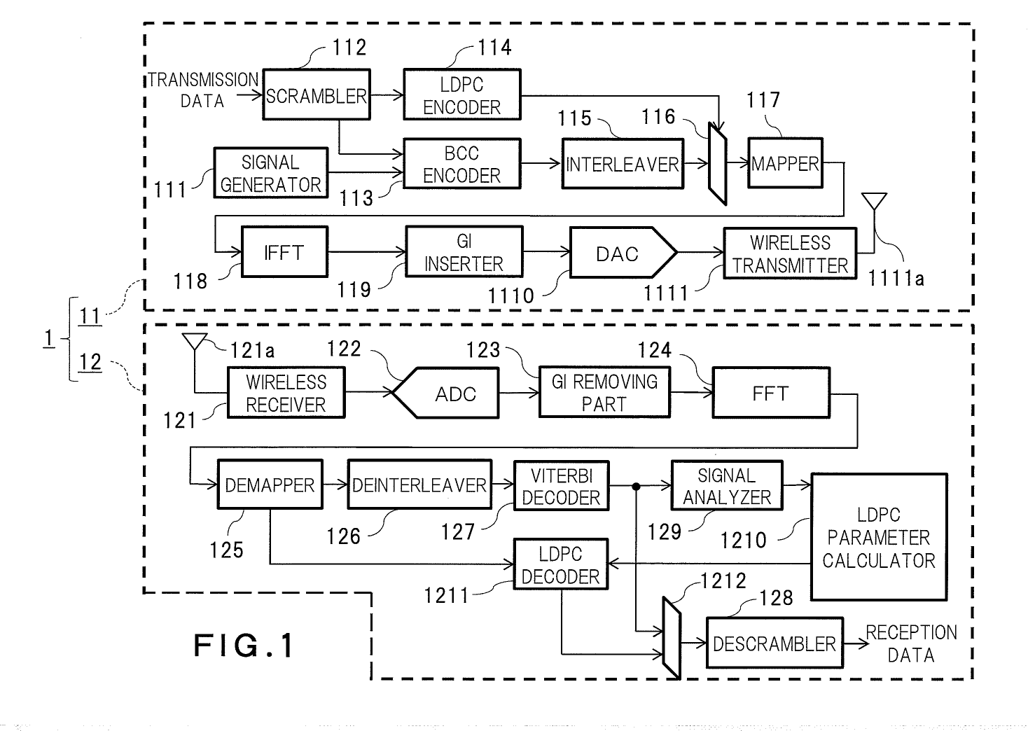

FIG. 1 is a block diagram of a communication system 1 according to the present embodiment. The communication system 1 includes a transmission device 11 and a reception device 12. The reception device 12 is also a communication apparatus. For example, the transmission device 11 transmits data to the reception device 12 with a communication method conforming to IEEE 802.11ac. The reception device 12 receives data transmitted from the transmission device 11. The transmission device 11 may further have functions of the reception device 12. The reception device 12 may further have functions of the transmission device 11.

As shown in FIG. 1, in order from the upstream in a transmission direction of transmission data to be transmitted to the reception device 12, the transmission device 11 includes a scrambler 112, a BCC encoder 113, an interleaver 115, and a selector 116. The transmission device 11 further includes a signal generator 111 inputting signal data to the BCC encoder 113. The transmission device 11 further includes an LDPC encoder 114 between the scrambler 112 and the selector 116. The LDPC encoder 114 is independent from the BCC encoder 113 and the interleaver 115 in the transmission order of transmission data.

The transmission device 11 further includes, in order at the downstream side of the selector 116, a mapper 117, an inverse-fast-Fourier-transform part (IFFT) 118, a GI (Guard Interval) inserter 119, a DAC (Digital to Analog Converter) 1110, and a wireless transmitter 1111 with an antenna 1111a.

In the VHT-SIG-B, the interleaver 115 rearranges bit positions of a second error-correction-code sequence in which two or more terminated first error-correction-code sequences are repeated across the first error-correction-code sequences. The bit positions are rearranged in accordance with a first rule. By rearranging the bit positions in accordance with the first rule, the interleaver 115 configures a third error-correction-code sequence. In fields other than the VHT-SIG-B, the interleaver 115 divides one terminated error-correction-code sequence to one or more sequences, closes the divided sequences, and rearranges bit positions. The interleaver 115 is described in more detail in an operation example of the communication system 1 described below.

Meanwhile, as shown in FIG. 1, in order from the upstream in a transmission direction of reception data received from the transmission device 11, the reception device 12 includes a wireless receiver 121 with an antenna 121a, an ADC (Analog to Digital Converter) 122, a GI removing part 123, and a fast-Fourier-transform part (hereinafter, also “FFT”) 124.

In order at the downstream side of the FFT 124, the reception device 12 further includes a demapper 125, a deinterleaver 126, a Viterbi decoder 127, a selector 1212, and a descrambler 128. The Viterbi decoder 127 is an example of an error corrector.

The reception device 12 further includes an LDPC decoder 1211 as an example of a decoder between the demapper 125 and the selector 1212. The LDPC decoder 1211 is independent from the deinterleaver 126 and the Viterbi decoder 127 in the transmission order of reception data The reception device 12 further includes a signal analyzer 129 and an LDPC parameter calculator 1210 between the Viterbi decoder 127 and the LDPC decoder 1211.

The deinterleaver 126 receives the third error-correction-code sequence as an input. The deinterleaver 126 rearranges bit positions of the input third error-correction-code sequence in accordance with a second rule that is different from the first rule. By rearranging the bit positions, the deinterleaver 126 configures a fourth error-correction-code sequence including one or more terminated first error-correction-code sequences. The second rule for the VHT-SIG-B used by the deinterleaver 126 is to extract bits capable of configuring the fourth error-correction-code sequence from the third error-correction-code sequence in order from the head. In fields other than the VHT-SIG-B, the deinterleaver 126 closes sequences divided by the same length as those in the transmitting side, rearranges bit positions, restores the divided sequences of the transmitting side, and combines the restored divided sequences. In this manner, one terminated error-correction-code sequence is configured. The deinterleaver 126 is described in more detail in the operation example of the communication system 1 described below.

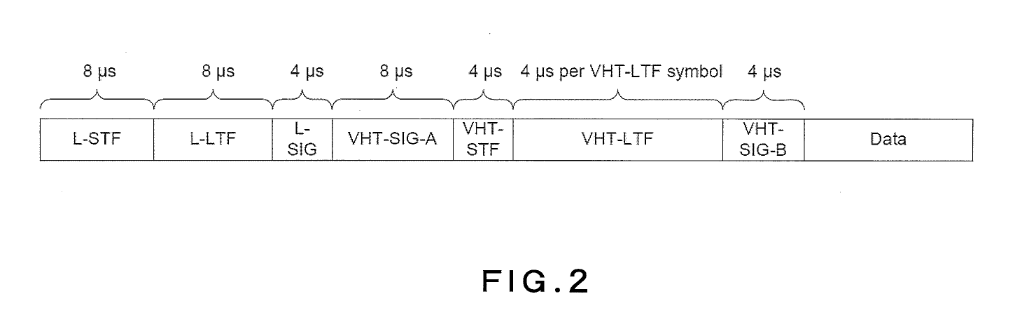

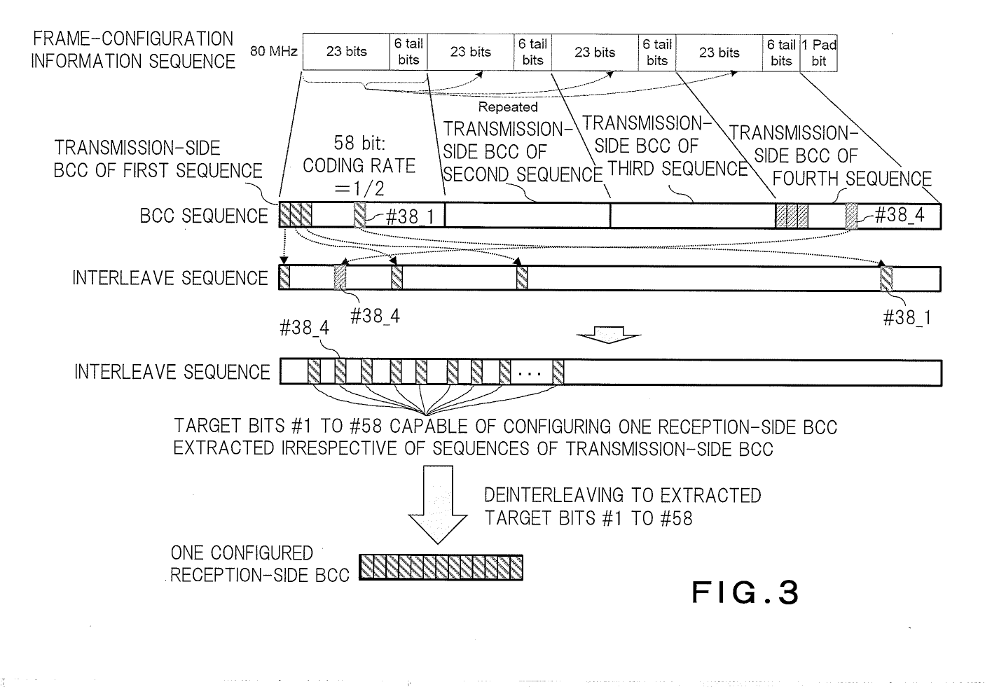

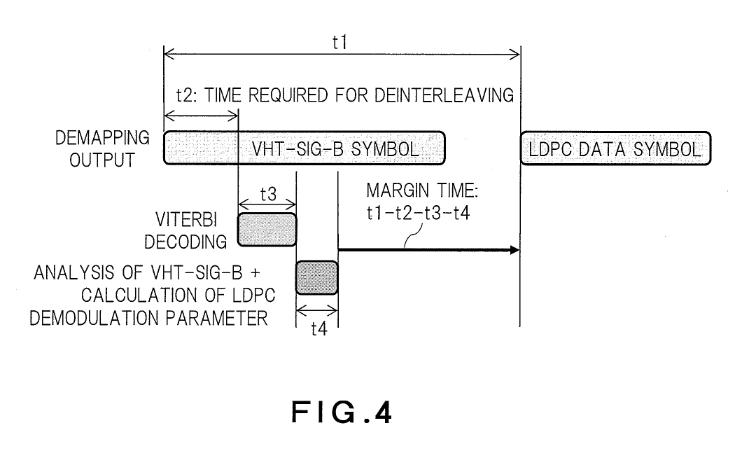

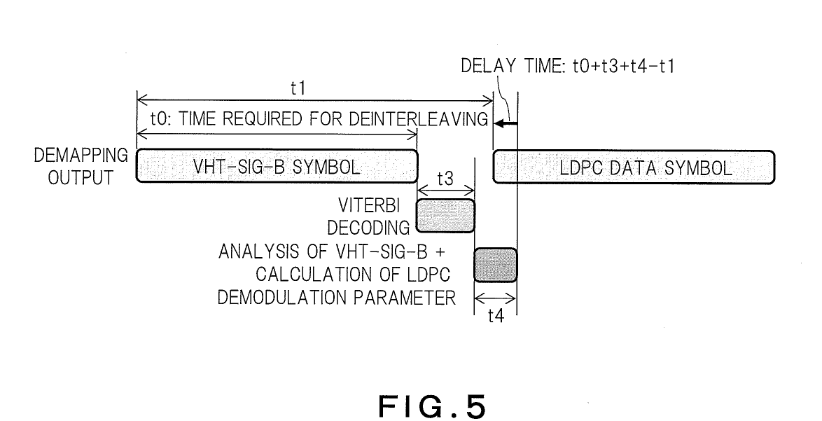

An example of the operation of the communication system 1 having the configuration described above is explained. FIG. 2 shows a frame format of IEEE 802.11ac. FIG. 3 shows an operation example of the communication system 1 in FIG. 1. FIG. 4 is a timing chart showing an operation example of the communication system 1 in FIG. 1. FIG. 5 is a timing chart showing an operation example of a communication system performing deinterleaving targeted on all bits of an interleave sequence as a communication system according to a comparative example.

First, a transmission process in the transmission device 11 is described. The transmission device 11 transmits transmission data of the frame format shown in FIG. 2 to the reception device 12.

The transmission data in FIG. 2 includes respective fields of an L-STF (Legacy-Short Training Field), an L-LTF (Legacy-Long Training Field), an L-SIG (Legacy-SIGNAL), and a VHT-SIG-A in order from the head. The frame format in FIG. 2 further includes respective fields of a VHT-STF, a VHT-LTF, a VHT-SIG-B, and a Data in this order, following the VHT-SIG-A. In the frame format in FIG. 2, fields other than the Data field are preambles for establishing synchronization of data transmission.

For example, the L-STF is used for AGC (Automatic Gain Control) and synchronization of timings/frequencies of OFDM (Orthogonal Frequency Division Multiplexing) symbols. The L-STF is a field having a duration of 8 μs. For example, the L-LTF is a field of 8 μs used for highly-accurate frequency synchronization or channel estimation. For example, the L-SIG is a field of 4 μs storing therein information such as a transmission rate or a data amount of the data of the Data field.

For example, the VHT-SIG-A is a field of 8 μs storing therein a bandwidth, an MCS, the number of time-space streams and the like. For example, the VHT-STF is a field of 4 μs used for improving estimation of AGC in MIMO (Multiple Input Multiple Output) transmission. For example, the VHT-LTF is a field of 4 μs used for MIMO channel estimation, equalization of received signals, and the like. A plurality of (for example, up to eight symbols of) VHT-LTFs are included in a corresponding field. The VHT-SIG-B is the last field of preambles. As described above, in the MU format, a data length and an MCS index are written in the VHT-SIG-B.

To transmit the frame format in FIG. 2, the signal generator 111 in FIG. 1 first generates a frame-configuration information sequence. The signal generator 111 then outputs the generated frame-configuration information sequence to the BCC encoder 113.

Next, the BCC encoder 113 in FIG. 1 converts the frame-configuration information sequence input from the signal generator 111 to a BCC sequence shown in FIG. 3 by BCC coding. The BCC sequence is an example of the second error-correction-code sequence. In configuring a BCC sequence, generally, tail bits constituted of a plurality of “0 (zero)”s are added to an input sequence (a frame-configuration information sequence). A BCC sequence generated from an input sequence including tail bits is referred to as “terminated BCC sequence”.

As shown in FIG. 3, the BCC sequence has two or more repeated transmission-side BCCs. Each of the transmission-side BCCs is a terminated BCC sequence. Specifically, the BCC sequence has four transmission-side BCCs of first to fourth sequences. The number of transmission-side BCCs is not limited to four as long as it is equal to or larger than two. The transmission-side BCC is an example of the first error-correction-code sequence. Each of the transmission-side BCCs of the second sequence and later is repeated one or a copy of the transmission-side BCC (that is, the terminated BCC sequence) of the first sequence. That is, the BCC sequence in FIG. 3 is formed of a plurality of copies of the “terminated BCC sequence” (the transmission-side BCC). The transmission-side BCC of the first sequence is repeated so that the error correction capability can be improved.

The specific mode of the BCC sequence is not limited to any particular mode as long as it is a mode of repeating the transmission-side BCC of the first-sequence. For example, as shown in FIG. 3, the transmission-side BCC of each sequence in the BCC sequence may be 58-bits data, which is obtained by encoding a frame-configuration information sequence of 29 bits in total with tail bits of 6 bits added at a coding rate of 1/2.

In FIG. 3, “#38_1” represents a 38th bit of the first sequence of the transmission-side BCC, and “#38_4” represents a 38th bit of the fourth sequence.

Next, the BCC encoder 113 outputs the BCC sequence obtained by BCC coding to the interleaver 115 in FIG. 1. The interleaver 115 performs interleaving on the BCC sequence to improve the burst error resilience of the BCC sequence input from the BCC encoder 113.

Interleaving is a process of rearranging respective bits of a BCC sequence in accordance with a predetermined order (the first rule). FIG. 3 shows an example of interleaving where the order of the 38th bit of the first sequence #38_1 is reversed with that of the 38th bit of the fourth sequence #38_4 by interleaving. The order for rearrangement of the bits in interleaving may be based on a predetermined numerical expression or function. In the interleaving process, the rearrangement occurs regardless of the above division of the “terminated BCC sequences”. That is, in some cases, the rearrangement occurs across a terminated BCC sequence in the front and a terminated BCC sequence in the subsequent part.

By interleaving, the bit positions of the BCC sequence are rearranged across the plurality of transmission-side BCCs (terminated BCC sequences) in accordance with the first rule, and thus the BCC sequence is converted to an interleave sequence. That is, by interleaving, the bit positions of the BCC sequence are rearranged from the transmission-side BCCs in accordance with the first rule, and thus the BCC sequence is converted to the interleave sequence. The interleave sequence is an example of the third error-correction-code sequence. The interleaver 115 outputs the interleave sequence to the selector 116 in FIG. 1.

Next, the selector 116 outputs the interleave sequence to the mapper 117. Next, the mapper 117 performs mapping of the interleave sequence input from the selector 116. Mapping is a process of converting an arrangement of pieces of data (a data sequence) in the interleave sequence to an arrangement (a sequence) of modulation symbols specified by an I (In-phase) component and a Q (Quadrature-phase) component. A modulation method in mapping is 256-QAM (Quadrature Amplitude Modulation), for example. Other examples of the modulation method include QPSK (Quadrature Phase Shift Keying), 16-QAM, and 64-QAM. The mapper 117 outputs the modulation symbol obtained by mapping of the IFFT 118.

The IFFT 118 performs inverse fast Fourier transform on the modulation symbol input from the mapper 117. The inverse fast Fourier transform is a process of converting the modulation symbol, which is a signal in a frequency domain (a spectral waveform), to a signal in a time domain (a temporal axis waveform).

The modulation symbol input to the IFFT 118 is a multicarrier constituted of individual subcarriers (channels) arranged in parallel, for example. The modulation symbol, which is a multicarrier, is multiplexed to a single wave by inverse fast Fourier transform. The IFFT 118 then outputs a signal of a temporal axis waveform obtained by the inverse fast Fourier transform to the GI inserter 119.

Next, the GI inserter 119 adds (inserts) a guard interval signal to the signal input from the IFFT 118. The guard interval signal is a signal with a fixed time interval added to avoid influences of multipath delay. The GI inserter 119 outputs the signal having the guard interval signal added thereto to the DAC 1110.

Next, the DAC 1110 converts the digital signal input from the GI inserter 119 to an analog signal. Subsequently, the DAC 1110 outputs the analog signal to the wireless transmitter 1111.

Next, the wireless transmitter 1111 transmits the analog signal input from the DAC 1110 on a carrier wave of a set transmission frequency (RF) to the reception device 12.

In this way, a signal field (a preamble) in the frame format in FIG. 2 is transmitted first. The transmitted signal field is received and demodulated by the reception device 12. Before detailed descriptions of a reception process in the reception device 12 are given, a transmission process of the Data field following the signal field is described.

As shown in FIG. 1, transmission data as data of the Data field is input to the scrambler 112. The scrambler 112 performs scrambling on the input transmission data. Scrambling is a process of calculating an exclusive OR of transmission data and a random signal formed of “0” and “1”. For example, even when all bits of transmission data are “0”, the transmission data can be converted to a signal including “1” by scrambling. Both “0” and “1” can be included in the transmission data, and thus encoding at the BCC encoder 113 described below can be appropriately performed.

When the transmission data is data specified to be BCC-coded, the scrambler 112 outputs the transmission data to the BCC encoder 113. On the other hand, when the transmission data is data specified to be LDPC-coded, the scrambler 112 outputs the transmission data signal to the LDPC encoder 114.

The BCC encoder 113 and the constituent parts 115 to 1111 at the subsequent stage of the BCC encoder 113 perform same processes as the above processes for the signal field to the transmission data. Meanwhile, the LDPC encoder 114 performs LDPC coding of the transmission data input from the scrambler 112. Subsequently, the LDPC encoder 114 outputs the LDPC-coded transmission data to the selector 116. That is, as for the LDPC-encoded transmission data, interleaving is omitted.

The reception process in the reception device 12, that is, a communication method thereof is described next. First, the reception device 12 receives a signal of a signal field transmitted from the transmission device 11. To demodulate the signal of the signal field, the reception device 12 performs a signal process basically inverse to the process performed by the transmission apparatus 11.

First, the wireless receiver 121 receives a signal at a reception frequency corresponding to a transmission frequency of the wireless transmitter 1111. Signals of the signal fields are received in order from the field closer to the head (L-STF) side in FIG. 2. The wireless receiver 121 outputs the received signal to the ADC 122.

Next, the ADC 122 converts an analog signal input from the wireless receiver 121 to a digital signal. Subsequently, the ADC 122 outputs the digital signal to the GI removing part 123.

Next, the GI removing part 123 removes a guard interval in the signal input from the ADC 122. Subsequently, the GI removing part 123 outputs the signal from which the guard interval has been removed to the FFT 124.

Next, the FFT 124 performs fast Fourier transform on the signal input from the GI removing part 123. Fast Fourier transform is a process of converting an input signal in a temporal axis domain to a signal in a frequency domain. In other words, fast Fourier transform is a process of branching the input signal for each subcarrier. Subsequently, the FFT 124 outputs the signal on which fast Fourier transform has been performed to the demapper 125.

Next, the demapper 125 performs demapping of the signal input from the FFT 124 in a demodulation method corresponding to the modulation method in mapping. Demapping is a process of demodulating a modulation symbol modulated by mapping. By performing demapping, an interleave sequence (see FIG. 3) is obtained. The demapper 125 outputs the interleave sequence to the deinterleaver 126.

Next, the deinterleaver 126 performs deinterleaving on the interleave sequence input from the demapper 125. That is, the deinterleaver 126 receives the interleave sequence as an input to rearrange bits of the interleave sequence (see FIG. 3). The deinterleaving process is completed to configure a BCC sequence (hereinafter, also “reconfigured BCC sequence”) including one or more reception-side BCC (a terminated BCC sequence) having the same contents as the transmission-side BCC. The reconfigured BCC sequence is an example of the fourth error-correction-code sequence. The reception-side BCC is an example of the fourth error-correction-code sequence. The reception-side BCC in FIG. 3 is an example of a terminated first error-correction-code sequence included in the fourth error-correction-code sequence. The reconfigured BCC sequence may include only one reception-side BCC. When only one reception-side BCC is included, the reception-side BCC is also a reconfigured BCC sequence.

To configure a reception-side BCC promptly, the deinterleaver 126 rearranges the bits of the interleave sequence in accordance with the second rule. Specifically, the deinterleaver 126 extracts a plurality of bits (target bits) capable of configuring a reconfigured BCC in order from the head of the interleave sequence. For example, the deinterleaver 126 extracts a plurality of (in the example in FIG. 3, 58) target bits capable of configuring one reception-side BCC as the reconfigured BCC sequence in order from the head of the interleave sequence. The target bits are bits capable of configuring the reception-side BCC and are bits belonging to a bit string having the smallest bit number counted from the head of the interleave sequence.

That is, the deinterleaver 126 extracts target bits irrespective of (ignoring) the sequences of the transmission-side BCCs. In other words, the interleaver 126 extracts target bits in a manner of putting a priority on the bit order over the sequence difference.

The deinterleaver 126 then rearranges the extracted target bits to configure one reception-side BCC.

Examples of deinterleaving different from the present embodiment include deinterleaving targeting all bits of an interleave sequence. Interleaving targeting all bits is constrained by sequences of transmission-side BCCs. For example, in deinterleaving targeting all bits, to configure a reception-side BCC of a first sequence, only bits configuring a transmission-side BCC of a first sequence are used and bits configuring a transmission-side BCC of a fourth sequence are not used. For example, although #38_4 (the 38th bit of the fourth sequence) in FIG. 3 is located at the head of the 38th bits in the interleave sequence, #38_4 is not extracted as a bit to configure a reception-side BCC of the first sequence. Accordingly, in deinterleaving targeting all bits, #38_4 does not contribute to prompt configuring of one reception-side BCC.

On the other hand, in interleaving in the present embodiment, the target bits are extracted irrespective of the sequences of the transmission-side BCCs, so that #38_4 located at the head of the 38th bits is extracted as a 38th bit to configure one reception-side BCC. In contrast, #38_1 located at the tail of the 38th bits is not extracted as a 38th bit to configure the reception-side BCC even when #38_1 is located at the head of the sequence of the transmission-side BCC.

The other bits located at the head of the interleave sequence are extracted as bits to configure the reception-side BCC in the same way as #38_4, even when these bits are located at the tail of the sequences of the transmission-side BCCs.

Bits located at the head of the interleave sequence can be preferentially extracted as target bits. Therefore, one reception-side BCC can be configured quickly. Because one reception-side BCC can be configured quickly, as described below, demodulation of LDPC-coded data of the Data field can be prevented from being delayed.

Deinterleaving in the present embodiment can be expressed as follows. First, as a premise, a terminated error code (that is, a first error-correction-code sequence) Xi is defined by the following expression.

Xi={Xi(1), Xi(2), . . . , Xi(m)} (I)

In the expression (I), i represents a sequence number (1≦i≦n), and 1 to m represent bit numbers.

A second error-correction-code sequence Y is defined by the following expression.

Y={X1, X2, . . . , Xn} (II)

The expression (II) is connection of Xi.

An interleave sequence Z is defined by the following expression using the second error-correction-code sequence Y.

Z=Interleave(Y) (III)

For example, the expression (III) can be specifically expressed as follows.

Z={X4(38), X1(32), X2(11), X3(58), . . . , X1(38)} (III-2)

In the expression (III-2), for example, the bit at the head of Z is the 38th bit of the fourth sequence. The second bit of Z is the 32nd bit of the first sequence. The bit at the tail of Z is the 38th bit of the first sequence.

With the above configuration as a premise, in deinterleaving, Z is converted to an interleave sequence Z(0) in which all bits included in Z are regarded as bits of a 0 sequence. For example, Z(0) can be specifically expressed by the following expression.

Z(0)={X0(38), X0(32), X0(11), X0(58), . . . , X0(38)} (IV)

The example of the expression (IV) corresponds to the example of the expression (III-2).

Next, a plurality of bits capable of configuring a fourth error-correction-code sequence X0 in the shortest time are extracted from the head of Z(0). X0 can be expressed by the following expression.

X0={X0(1), X0(2), . . . , X0(m)} (V)

Subsequently, the extracted bits are rearranged to configure the fourth error-correction-code sequence X0.

It is possible that the deinterleaver 126 obtains order information (for example, a numerical expression) about the order for rearrangement of bits in interleaving as the first rule in advance, thereby extracting (recognizing) a plurality of target bits based on the order information. Due to the order information, target bits can be easily and properly extracted.

Next, the deinterleaver 126 outputs one BCC reception-side BCC (an example of a reconfigured BCC sequence) obtained by deinterleaving to the Viterbi decoder 127.

Next, the Viterbi decoder 127 performs Viterbi-decoding on the reception-side BCC input from the deinterleaver 126. Errors of a signal can be corrected by Viterbi-decoding. As described above, because the number of the reception-side BCC input to the Viterbi decoder 127 is one, for example, Viterbi-decoding can be quickly performed on the reception-side BCC. Subsequently, the Viterbi decoder 127 outputs a signal on which Viterbi-decoding is performed to the signal analyzer 129.

Next, the signal analyzer 129 analyzes the signal input from the Viterbi decoder 127 and outputs analysis information for calculation of an LCPC demodulation parameter to the LDPC parameter calculator 1210. The analysis information may be the MCS of the VHT-SIG-B, for example.

Next, the LDPC parameter calculator 1210 calculates an LDPC demodulation parameter based on the analysis information input from the signal analyzer 129. When at least one reception-side BCC has been demodulated, the LDPC parameter calculator 1210 can calculate an LDPC demodulation parameter based on the analysis information of the demodulated data. In the present embodiment, based on analysis information of the demodulated data of one reception-side BCC, an LDPC demodulation parameter can be quickly calculated. Subsequently, the LDPC parameter calculator 1210 outputs the calculated LDPC demodulation parameter to the LDPC decoder 1211.

Next, the reception device 12 receives the Data field transmitted from the transmission apparatus 11. It is assumed here that the signal of the Data field (data subsequent to an interleave sequence) has been LDPC-decoded. The signal of the Data field is processed by the wireless receiver 121, the ADC 122, the GI removing part 123, the FFT 124, and the demapper 125 sequentially, in the same manner as the signal of the signal field. After demapping, interleaving on the signal of the Data field is omitted and the signal is input to the LDPC decoder 1211. The signal of the Data field is an LDPC-coded signal on which interleaving is omitted after LDPC coding. Therefore, deinterleaving on the signal of the Data field is omitted.

When the Data field is input, an LDPC demodulation parameter has been already input to the LDPC decoder 1211. Therefore, the LDPC decoder 1211 can demodulate the LDPC data based on the LDPC demodulation parameter without fail. As scrambling of the data decoded by the LDPC decoder 1211 is canceled at the descrambler 128, the decoded data is converted to reception data.

As described above, in the present embodiment, the target of deninterleaving can be limited to one reception-side BCC. As a result, for example, as shown in FIG. 4, an LDPC demodulation parameter can be calculated within a time t2+t3+t4, which is shorter than the time t1 from completion (output) of damapping of the VHT-SIG-B symbol to completion of demapping of the LDPC data symbol (data of the Data field).

The time t2 is a time required for performing deinterleaving on target bits. The time t3 is a time required for Viterbi decoding. The time t4 is a time required for analyzing a VHT-SIG-B symbol and calculating an LDPC demodulation parameter.

As shown in FIG. 4, there is a sufficient margin time t1−t2−t3−t4 from completion of calculating the LDPC demodulation parameter to completion of demapping of the LDPC data symbol. Therefore, the data of the Data field can be demodulated based on the LDPC demodulation parameter with a sufficient time margin.

When deinterleaving targeting all bits is applied, the reception device needs to wait to perform processes subsequent to deinterleaving until deinterleaving on all bits of the VHT-SIG-B symbol is completed. Specifically, as shown in FIG. 5, Viterbi decoding cannot be started until the time t0 required for performing deinterleaving on the entire VHT-SIG-B symbol has passed. Therefore, a time obtained by adding the time t3+t4 required for Viterbi decoding, analysis, calculation of an LDPC demodulation parameter to the t0 often becomes longer than the time t1 from the completion of demapping of the VHT-SIG-B symbol to the completion of demapping of the LDPC data symbol. In this case, when demapping of the LDPC data symbol is completed, the LDPC demodulation parameter has not been calculated, and thus the LDPC data symbol cannot be demodulated. Calculation of an LDPC demodulation parameter needs to be waited after completion of demapping of the LDPC data symbol, and thus, as shown in FIG. 5, a delay time t0+t3+t4−t1 is generated in demodulation of the LDPC data symbol.

On the other hand, the LDPC decoder 1211 according to the present embodiment can obtain the LDPC demodulation parameter sufficiently in advance to the completion of demapping of the LDPC data symbol. Therefore, the LDPC data symbol can be demodulated without any delay after the completion of demapping.

The deinterleaver 126 may change the number of reception-side BCCs to be included in a reconfigured BCC sequence according to a time required for configuring the reconfigured BCC sequence. For example, in FIG. 4, when t2+t3+t4 can be equal to or shorter than t1, the deinterleaver 126 can configure the reconfiguration BCC sequence by two or more reception-side BCCs. The deinterleaver 126 may analyze the order (the first rule) of bits of the interleave sequence based on the order information described above to calculate the number of reception-side BCCs to be included in the reconfigured BCC sequence so as to make t2+t3+t4 equal to or shorter than t1. The reconfigured BCC sequence is configured by a plurality of reception-side BCCs so that the Viterbi decoder 127 can perform error correction based on the plurality of reception-side BCCs. Due to this configuration, while demodulation of the data of the Data field is prevented from being delayed, the error-correction capability can be improved.

As the wireless communication method of the communication system 1, methods other than IEEE 802.11ac can be also used.

As described above, according to the present embodiment, bits capable of configuring a reconfigured BCC sequence (a reception-side BCC) promptly are extracted preferentially and deinterleaving is performed on the bits so that data of a Data field can be demodulated quickly without any latency. That is, the communication apparatus 12 and the communication system 1 according to the present embodiment can demodulate data quickly.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A communication apparatus comprising:
a deinterleaver setting, as an input, a third error-correction-code sequence obtained by rearranging bit positions of a second error-correction-code sequence in which two or more terminated first error-correction-code sequences are repeated from the terminated first error-correction-code sequences in accordance with a first rule, and rearranging bit positions of an input third error-correction-code sequence in accordance with a second rule that is different from the first rule to configure a fourth error-correction-code sequence including one or more of the terminated first error-correction-code sequences; and
an error corrector that performs error correction based on the fourth error-correction-code sequence, wherein
the second rule used by the deinterleaver is to extract bits capable of configuring the fourth error-correction-code sequence in order from a head of the third error-correction-code sequence.

2. The apparatus of claim 1, wherein the bits capable of configuring the fourth error-correction-code sequence include a bit group belonging to a bit string having a smallest bit number counted from the head of the third error-correction-code sequence.

3. The apparatus of claim 1, further comprising a decoder that decodes data subsequent to the third error-correction-code sequence based on the fourth error-correction-code sequence.

4. The apparatus of claim 3, wherein the deinterleaver changes number of the terminated first error-correction-code sequences to be included in the fourth error-correction-code sequence according to a time required for configuring the fourth error-correction-code sequence.

5. The apparatus of claim 3, wherein the decoder decodes the subsequent data while omitting deinterleaving.

6. The apparatus of claim 1, wherein the deinterleaver comprises information regarding the first rule, and extracts bits capable of configuring the fourth error-correction-code sequence based on the information.

7. A communication system comprising:
a transmission device; and
a reception device, wherein
the transmission device comprises an interleaver rearranging bit positions of a second error-correction-code sequence in which two or more terminated first error-correction-code sequences are repeated from the terminated first error-correction-code sequences in accordance with a first rule to configure a third error-correction-code sequence,
the reception device comprises
a deinterleaver receiving the third error-correction-code sequence as an input, and rearranging bit positions of an input third error-correction-code sequence in accordance with a second rule that is different from the first rule to configure a fourth error-correction-code sequence including one or more of the terminated first error-correction-code sequences, and
an error corrector that performs error correction based on the fourth error-correction-code sequence, and wherein
the second rule used by the deinterleaver is to extract bits capable of configuring the fourth error-correction-code sequence in order from a head of the third error-correction-code sequence.

8. The system of claim 7, wherein the bits capable of configuring the fourth error-correction-code sequence include a bit group belonging to a bit string having a smallest bit number counted from the head of the third error-correction-code sequence.

9. The system of claim 7, wherein the reception device further comprises a decoder that decodes data subsequent to the third error-correction-code sequence based on the fourth error-correction-code sequence.

10. The system of claim 9, wherein the deinterleaver changes number of the terminated first error-correction-code sequences to be included in the fourth error-correction-code sequence according to a time required for configuring the fourth error-correction-code sequence.

11. The system of claim 9, wherein the decoder decodes the subsequent data while omitting deinterleaving.

12. The system of claim 7, wherein the deinterleaver comprises information regarding the first rule, and extracts bits capable of configuring the fourth error-correction-code sequence based on the information.

13. A communication method comprising:
setting, as an input, a third error-correction-code sequence obtained by rearranging bit positions of a second error-correction-code sequence in which two or more terminated first error-correction-code sequences are repeated from the terminated first error-correction-code sequences in accordance with a first rule, and rearranging bit positions of an input third error-correction-code sequence in accordance with a second rule that is different from the first rule to configure a fourth error-correction-code sequence including one or more of the terminated first error-correction-code sequences; and
performing error correction based on the fourth error-correction-code sequence, wherein
the second rule is to extract bits capable of configuring the fourth error-correction-code sequence in order from a head of the third error-correction-code sequence.

14. The method of claim 13, wherein the bits capable of configuring the fourth error-correction-code sequence include a bit group belonging to a bit string having a smallest bit number counted from the head of the third error-correction-code sequence.

15. The method of claim 13, wherein data subsequent to the third error-correction-code sequence is decoded based on the fourth error-correction-code sequence.

16. The method of claim 15, wherein number of the terminated first error-correction-code sequences to be included in the fourth error-correction-code sequence is changed according to a time required for configuring the fourth error-correction-code sequence.

17. The method of claim 15, wherein the subsequent data is decoded while omitting deinterleaving.

18. The method of claim 13, wherein bits capable of configuring the fourth error-correction-code sequence are extracted based on information regarding the first rule.
